(19) United States
(12) Patent Application Publication
(10) Pub. No.: US 2011/0095808 A1
(43) Pub. Date: Apr. 28, 2011

(54) System and Method for Controlling Powered Device With Detachable, Controllable Switching Device

(76) Inventor: Colin Reason, Purbrook (GB)

(21) Appl. No.: 12/684,517

(22) Filed: Jan. 8, 2010

Related U.S. Application Data
(60) Provisional application No. 61/252,839, filed on Oct. 19, 2009.

(51) Int. Cl. H03K 17/56

(52) U.S. Cl. 327/419

(57) ABSTRACT

A device is provided for use with a power supply line and an electrical unit. The power supply line has a first connecting portion, whereas the electrical unit has a second connecting portion. The first connecting portion can detachably connect with the second connecting portion. The electrical unit can perform a function when the first connecting portion is electrically connected to the second connecting portion. The electrical unit can further consume power provided from the power supply line when not performing the function. The device includes a third connecting portion, a fourth connecting portion, a switching device and a control line. The third connecting portion can detachably connect to the first connecting portion. The fourth connecting portion can detachably connect to the second connecting portion. The switching device can electrically connect the third connecting portion to the fourth connecting portion when in a first state and can electrically disconnect the third connecting portion from the fourth connecting portion when in a fourth state. The control line can switch the switching device from the first state to the second state.

The present application claims priority from U.S. Provisional Application No. 61/252,839 filed Oct. 19, 2009, the entire disclosure of which is incorporated herein by reference.

### BACKGROUND

In today's electronic industry there is immense pressure on manufacturers to design products and provide solutions that offer higher energy efficiency and a smaller carbon footprint than products manufactured in the past. These new designs clearly benefit the environment but also offer the additional advantage to the end user of reduced operating costs.

On more recent and newly manufactured electronic products there are many solutions and practices that have been adopted by industry that now benefit new designs in this area. However, there is still a huge opportunity to provide simple energy-saving solutions for legacy products still in operation.

In the majority of electronic cabinets and systems, an external AC or DC voltage source is supplied to the equipment. This voltage can then be either distributed from the cabinet to various modules and subsystems or it can be converted into a number of different usable voltage rails, within the cabinet, which are then distributed within the equipment.

Most electronic cabinets and systems will distribute their power internally to different parts of the system, using cable harnesses along with a selection of different plugs and sockets for interfacing to different sub assemblies and modules.

Conventional redesign of electronic equipment to incorporate power-saving features tends to be very expensive, as the equipment typically has to be redesigned from scratch.

What is needed is a way to control the on/off state of electronic equipment and its subcomponents and to modify legacy electronic equipment in an economical way such that the on/off state of the equipment or its subcomponents can be controlled for reducing power consumption when the equipment or its subcomponents are in a non-functional mode of operation. Being able to modify legacy electronic equipment such that it is capable of controlling power consumption by turning off the equipment or it subcomponents when the equipment is not required to be operating would serve to provide equipment which satisfies efficiency goals and is also economical to implement.

### BRIEF SUMMARY

It is an object of the present invention to provide a system and method to control the on/off state of electronic equipment and its subcomponents and to modify legacy electronic equipment in an economical way such that the on/off state of the equipment or its subcomponents can be controlled for reducing power consumption when the equipment or its subcomponents are in a non-functional mode of operation.

In accordance with an aspect of the present invention, a device is provided for use with a power supply line and an electrical unit. The power supply line has a first connecting portion, whereas the electrical unit has a second connecting portion. The first connecting portion can detachably connect with the second conneting portion. The electrical unit can perform a function when the first connecting portion is electrically connected to the second connecting portion. The electrical unit can further consume power provided from the power supply line when not performing the function. The device inclues a third connecting portion, a fourth connecting portion, a switching device and a control line. The third connecting portion can detachably connect to the first connecting portion. The fourth connecting portion can detachably connect to the second connecting portion. The switching device can electrically connect the third connecting portion to the fourth connecting portion when in a first state and can electrically disconnect the third connecting portion from the fourth connecting portion when in a fourth state. The control line can switch the switching device from the first state to the second state.

Additional advantages and novel features of the invention are set forth in part in the description which follows, and in part will become apparent to those skilled in the art upon examination of the following or may be learned by practice of the invention. The advantages of the invention may be realized and attained by means of the instrumentalities and combinations particularly pointed out in the appended claims.

### BRIEF SUMMARY OF THE DRAWINGS

The accompanying drawings, which are incorporated in and form a part of the specification, illustrate example embodiments of the present invention and, together with the description, serve to explain the principles of the invention. In the drawings:

FIG. 1 illustrates an example use of a Controllable Switch Array (CSA), in accordance with an aspect of the present invention;

FIG. 2A illustrates a conventional electrical connector assembly for providing electrical power to an electrical unit;

FIG. 2B illustrates an example embodiment of the present invention where a CSA controls the on/off state of power provided to an electrical unit;

FIG. 3A illustrates a conventional fuse and fuse holder assembly;

FIG. 3B illustrates an example embodiment of the present invention where a CSA controls the on/off state of power provided to electrical equipment via interruption of power between a fuse assembly and a fuse holder;

FIG. 4 illustrates an example of an electrical power distribution system;

FIG. 5 is the distributed electrical power distribution system illustrated in FIG. 4 with the addition of an example aspect of the present invention;

FIG. 6 is the distributed electrical power distribution system illustrated in FIG. 4 and FIG. 5 with the addition of an example aspect of the present invention provided for externally controlling the on/off state of the system;

FIG. 7 is the distributed electrical power distribution system illustrated in FIG. 4 through FIG. 6 with the addition of an example aspect of the present invention provided for externally controlling the on/off state of the system via multiple control units; and

FIG. 8 is the distributed electrical power distribution system illustrated in FIG. 4 through FIG. 7 with the addition of an example aspect of the present invention provided for externally controlling the on/off state of a portion of the system via multiple control units and also controlling the on/off state of the remaining portion of the system via internal control.

### DETAILED DESCRIPTION

In accordance with an aspect of the present invention a controllable switch array (CSA) is operable to controllably cut off power to an electrical device when the electrical device is not in use, in order to reduce energy consumption. This aspect of the present invention provides an energy-saving solution that may be implemented in legacy electronic cabinets and systems already deployed in the field. This aspect of the present invention additionally may benefit design concepts and solutions for higher energy efficiency products of the future.

In an example embodiment of the present invention, a CSA takes advantage of legacy power architecture by presenting itself as a module that fits inline between the incoming power source and terminating sub assembly or module. This example CSA provides a “Power Conduit” that gives access to voltage/power line(s) and allows these lines to be controlled to either an ON or OFF state. As such, this example CSA provides a method of controlling the power provided to the sub assembly or modules within the system, on demand, and ultimately, the power drawn by this system.

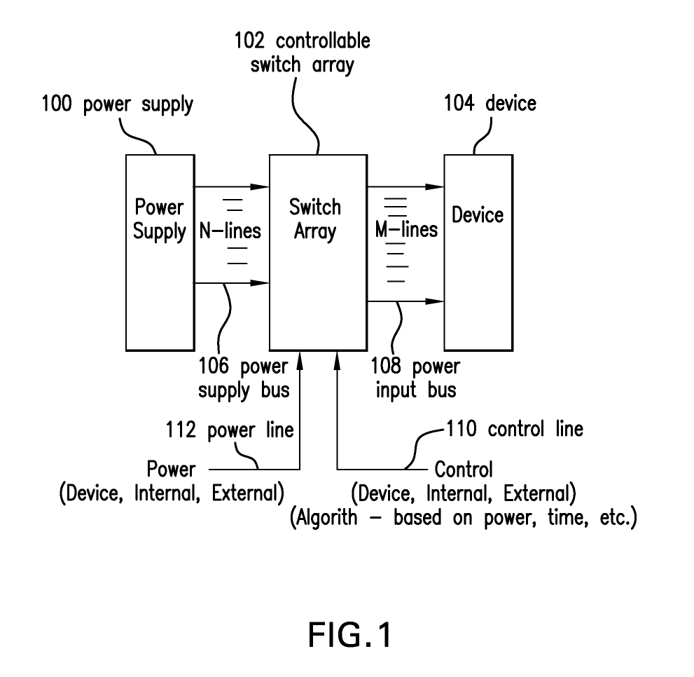

FIG. 1 illustrates an example use of a CSA, in accordance with an aspect of the present invention.

The figure includes a power supply 100, a CSA 102, a device 104, a power supply bus 106, a power input bus 108, a control line 110 and a power line 112.

Power supply 100 provides N-lines of electrical power to CSA 102 via power supply bus 106. CSA 102 processes the N-lines of electrical power provided on power supply bus 106 to generate M-lines of electrical power, which is provided to device 104 via power input bus 108. In most cases the number of lines of power supply bus 106 equal the number of lines of power input bus 108, such that N=M. However, there may be situations where the number of lines of power supply bus 106 do not equal the number of lines of power input bus 108, such that N≠M.

Power line 112 provides electrical power to CSA 102. Control line 110 provides control information to CSA 102 for configuring and controlling the electrical power provided on power input bus 108.

CSA 102 processes the electrical power provided on power supply bus 106, subject to the information received on control line 110, to provide the appropriate electrical power to power input bus 108. CSA 102 controls the on/off state of the power supplied to power input bus 108. CSA 102 may include switching devices, non-limiting examples of which include relays, transistors and diodes.

Control line 110 may be wired or wireless. Control line 110 can consist of a single control line carrying all of the necessary control information or can consist of multiple control lines for providing the necessary control information.

Power for power line 112 may be provided by power supply 100 or by an external power supply (not shown). In some embodiments, power line 112 is not included. In some embodiments, electrical power for CSA 102 is provided by power supply bus 106. In some embodiments, electrical power for CSA 102 is provided by an internal power supply source, a non-limiting example of which includes a battery.

FIG. 1 illustrates an example use of an embodiment of the present invention. A CSA processes electrical power provided by a power supply to provide electrical power to a device, subject to control information received via a control line. The information received via the control line configures the on/off state of the electrical power supplied to the device.

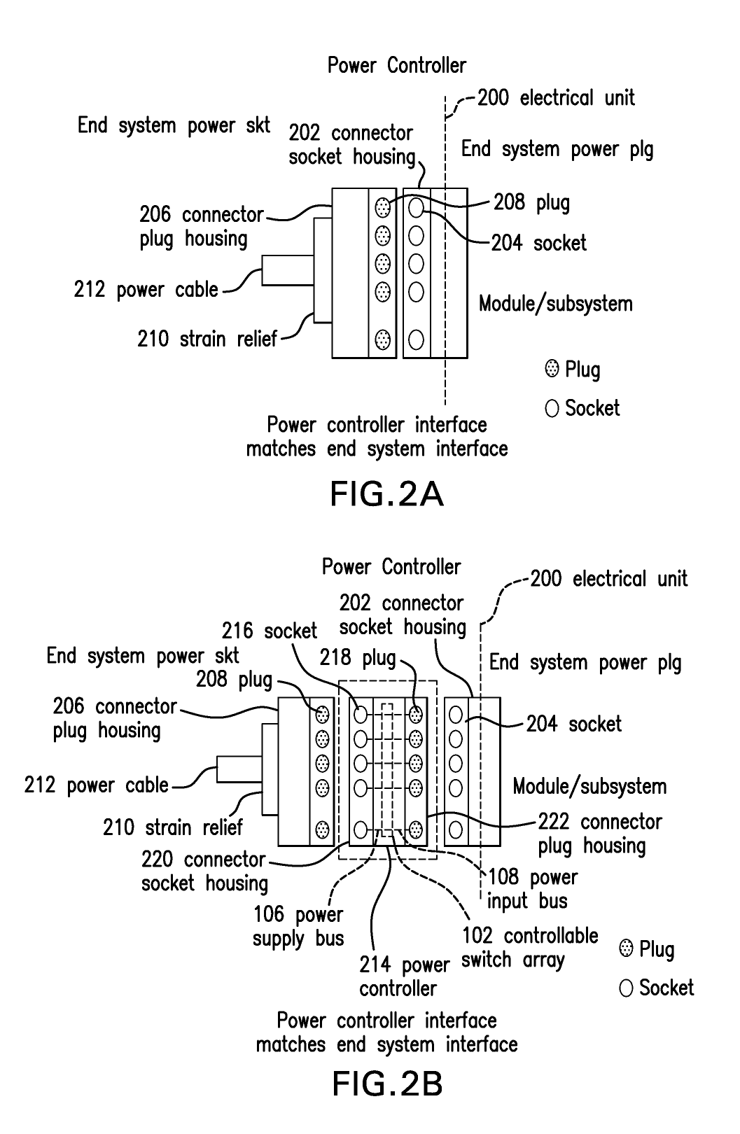

An example application of an embodiment of the present invention will now be described with reference to FIGS. 2A-2B.

FIG. 2A illustrates a conventional electrical connector assembly for providing electrical power to an electrical unit.

The figure includes an electrical unit 200, a connector socket housing 202, a socket 204, a connector plug housing 206, a plug 208, a strain relief 210 and a power cable 212.

Connector socket housing 202 is attached to electrical unit 200. Socket 204 is located within connector socket housing 202 and provides a path for electrical power to be supplied to electrical unit 200. Connector plug housing 206 connects to connector socket housing 202. Connector plug housing 206 can be inserted or removed from connector socket housing 202.

Plug 208 is located within connector plug housing 206. Strain relief 210 is attached to connector plug housing 206 and to power cable 212. Strain relief 210 provides mechanical support between power cable 212 and connector plug housing 206 to prevent damage from occurring between power cable 212 and connector plug housing 206. Power cable 212 extends through strain relief 210 and connects to connector plug housing 206.

An electrical wire (not shown) located within power cable 212 connects to plug 208.

When connector plug housing 206 is inserted into connector socket housing 202, plug 208 and socket 204 make mechanical and electrical contact. When connector plug housing 206 and connector socket housing 202 are connected, electrical power flows from electrical power source (not shown) through a wire located within power cable 212, plug 208 and socket 204. The electrical power is then distributed from socket 204 through connector socket housing 202 and distributed to electrical unit 200.

FIG. 2B illustrates an example embodiment of the present invention where a CSA controls the on/off state of power provided to an electrical unit.

The figure includes the elements of FIG. 2A, in addition to a power controller 214, a socket 216, a plug 218, a connector socket housing 220 and a connector plug housing 222.

Power controller 214 is disposed between connector plug housing 206 and connector socket housing 202.

Connector socket housing 220 is located within power controller 214. Socket 216 is located within connector socket housing 220 and is connected to power supply bus 106. Connector plug housing 222 is located within power controller 214. Plug 218 is located within connector plug housing 222 and is connected to power input bus 108.

Connector plug housing 222 arranged for connection with connector socket housing 202. Connector plug housing 206 is arranged for connection with connector socket housing 220.

When connector plug housing 206, power controller 214 and connector socket housing 202 are assembled, CSA 102 provides control of the ON/OFF state of the electrical power supplied to electrical unit 200.

When CSA 102 dictates that the power to electrical unit 200 is to be provided by socket 204, an electrical circuit located within CSA 102 is configured to enable the transmission of power from power supply bus 106 to power input bus 108. In such a case, electrical power flows from a power supply (not shown) through a wire (not shown) located within power cable 212, through plug 208, then through socket 216, then through power supply bus 106, then through CSA 102, then through power input bus 108, then through plug 218 and finally through socket 204. From socket 204, electrical power is distributed throughout electrical unit 200.

When CSA 102 dictates that power is not to be provided to electrical unit 200, the electrical circuit located within CSA 102 is configured to prevent the transmission of power to power input bus 108.

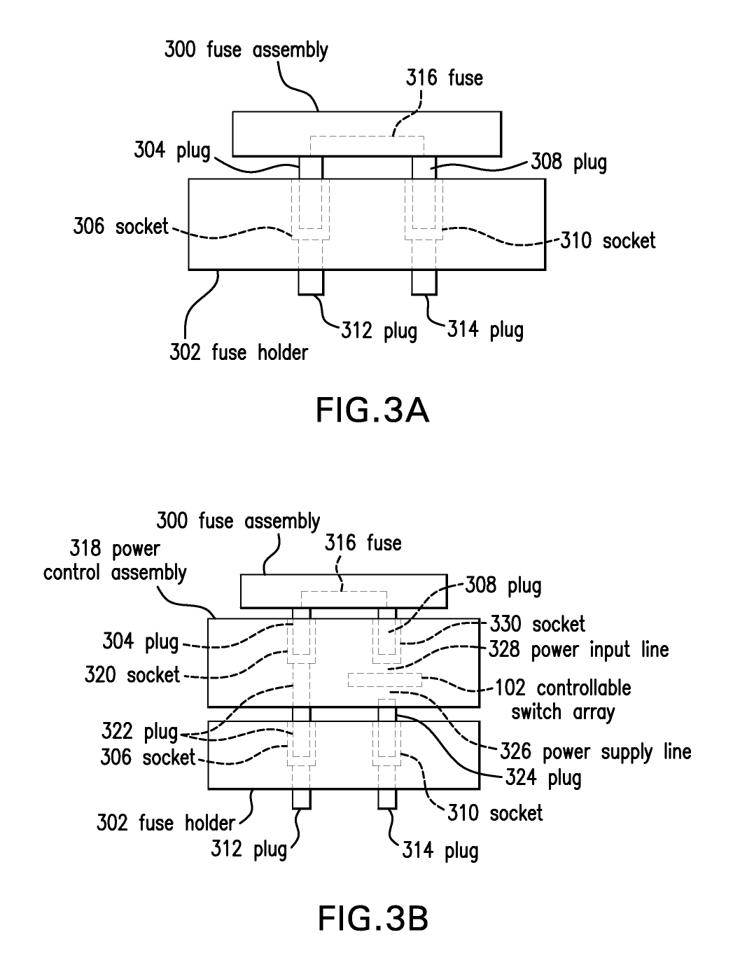

FIG. 2B illustrates an example embodiment of the present invention where a CSA controls the on/off state of power provided to an electrical unit. The CSA resides internal to a power controller, which is inserted between an existing connector plug and connector socket. Aspects of the present invention enable existing or legacy electronic equipment with this type of common connector configuration to be retrofitted in such a way as to enable the equipment to be controlled in such a way as to reduce power consumption by turning off non-operational equipment. Another example application of an embodiment of the present invention will now be described with reference to FIG. 3A and FIG. 3B.

FIG. 3A illustrates a conventional fuse and fuse holder assembly.

The figure includes a fuse assembly 300, a fuse holder 302, a plug 304, a socket 306, a plug 308, a socket 310, a plug 312, a plug 314 and a fuse 316.

Fuse assembly 300 mechanically and electrically connects to fuse holder 302. Plug 304 and plug 308 are connected to fuse assembly 300. Plug 304 and plug 308 are electrically connected via fuse 316, which is contained within fuse assembly 300.

Fuse holder 302 is able to connect to fuse assembly 300 by socket 306 and socket 310. Socket 306 and socket 310 are contained within fuse holder 302. Socket 306 receives plug 304 for making an electrical and mechanical connection. Socket 310 receives plug 308 for making an electrical and mechanical connection.

Socket 306 is connected to plug 312. Plug 312 resides partially within fuse holder 302 and partially external to fuse holder 302. Socket 310 is connected to plug 314. Plug 314 resides partially within fuse holder 302 and partially external to fuse holder 302. Plug 312 and plug 314 provide electrical and mechanical connection to an electrical assembly (not shown).

When fuse assembly 300 is connected to fuse holder 302 an electrical path is provided between plug 312 and plug 314. The electrical path between plug 312 and plug 314 begins at plug 312 and proceeds to socket 306, to plug 304, to fuse 316, to plug 308, to socket 310 and finally to plug 314. If at some point, the current rating of fuse assembly 300 had been surpassed, fuse 316 will be disrupted and the electrical path located between plug 304 and plug 308 will be terminated. When an electrical path between plug 304 and plug 308 has been terminated, an electrical path is also no longer provided between plug 312 and plug 314.

The capability for terminating the electrical path through fuse assembly 300 provides a way for protecting electrical and electronic equipment from excessive electrical currents. Excessive electrical currents have the capability to incur significant damage and destruction if not terminated. Excessive electrical currents can cause fire, smoke, damage to property and loss of life.

FIG. 3B illustrates an example embodiment of the present invention where a CSA controls the ON/OFF state of power provided to electrical equipment via interruption of power between a fuse assembly and a fuse holder.

FIG. 3B includes the elements of FIG. 3A, in addition to a power control assembly 318, a socket 320, a plug 322, a plug 324, a power supply line 326, a power input line 328 and a socket 330.

Socket 320 is contained within power control assembly 318 and is connected to plug 322. Plug 322 is partially contained within power control assembly 318 and partially extrudes from power control assembly 318.

Socket 330 is contained within power control assembly 318. Power input line 328 is contained within power control assembly 318 and provides an electrical path between socket 330 and CSA 102. Power supply line 326 is contained within power control assembly 318 and provides an electrical path between CSA 102 and plug 324. Plug 324 is partially contained within power control assembly 318 and partially extrudes from power control assembly 318.

Power control assembly 318 connects to and is located between fuse assembly 300 and fuse holder 302. Plug 304 connects to socket 320. Plug 308 connects to socket 330. Plug 322 connects to socket 306. Plug 324 connects to socket 310.

When fuse 316 is not terminated, CSA 102 is operable to provide an electrical connection between power input line 328 and power supply line 326. Thus an electrical path is provided between plug 314 and plug 312. The electrical path starts at plug 314 and proceeds to socket 310, to plug 324, to power supply line 326, to CSA 102, to power input line 328, to socket 330, to plug 308, to fuse 316, to plug 304, to socket 320, to plug 322, to socket 306 and finally to plug 312. If fuse 316 is terminated or CSA 102 is controlled to provide an open circuit, then an electrical path is not provided between plug 312 and plug 314.

FIG. 3B illustrates how an example aspect of the present invention can provide an on/off capability for electrical equipment via insertion of a power control assembly containing a CSA between a fuse and a fuse holder. It is very common for electronic equipment to be protected by fuses. This example aspect of the present invention enables legacy electronic equipment to be modified by simply inserting a power control assembly containing a CSA between the fuse and its respective fuse holder. The electronic equipment can be controlled for power efficiency and also continue to be protected by safety circuitry, such as a fuse.

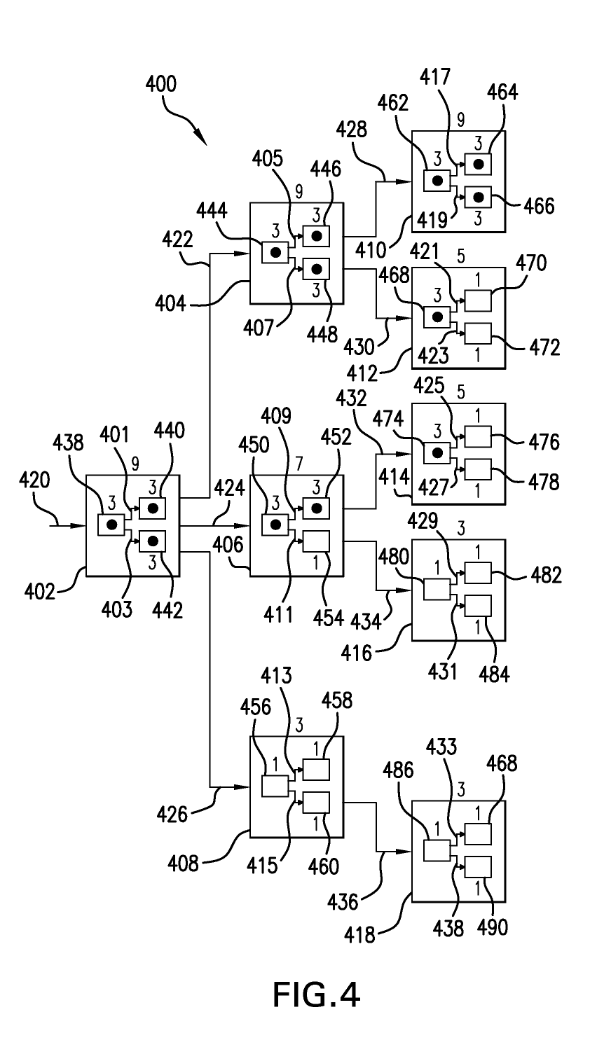

Further example applications for embodiments of the present invention related to distributed power systems will now be described with reference to FIG. 4 through FIG. 8.

FIG. 4 illustrates an example electrical power distribution system 400.

Electrical power distribution system 400 includes an electrical unit 402, an electrical unit 404, an electrical unit 406, an electrical unit 408, an electrical unit 410, an electrical unit 412, an electrical unit 414, an electrical unit 416 and an electrical unit 418.

Each electrical unit within electrical power distribution system 400 is operable to receive electrical power from a power input line, perform some function when required, consume power when performing the function and provide power to a downstream electrical unit as required.

For purposes of discussion, electrical power distribution system 400 is arranged such that electrical unit 402 receives electrical power from a power line 420. Further, electrical unit 402 is arranged to provide electrical power to electrical unit 404, electrical unit 406 and electrical unit 408 by way of a power line 422, a power line 424 and a power line 426, respectively. Electrical unit 404 is arranged to provide electrical power to electrical unit 410 and electrical unit 412 by way of a power line 428 and a power line 430, respectively. Electrical unit 406 is arranged to provide electrical power to electrical unit 414 and electrical unit 416 by way of a power line 432 and a power line 434, respectively. Electrical unit 408 is arranged to provide electrical power to electrical unit 418 by way of a power line 436.

As discussed briefly above, each electrical unit within electrical power distribution system 400 may consume electrical power when in operation. Further, electrical unit 402, electrical unit 404, electrical unit 406 and electrical unit 408 are operable to provide electrical power to other electrical units. Additionally, each electrical unit within electrical power distribution system 400 may have sub-units therein, which are additionally able to consume power.

For purposes of explanation, presume in this example that each electrical unit within electrical power distribution system 400 includes three electrical sub-units that are each operable to perform a function and consume power while performing the function. Each electrical unit is itself configured as an electrical power distribution system. A first electrical sub-unit within each electrical unit is capable of receiving and providing electrical power. The remaining electrical sub-units within each electrical unit are capable of receiving electrical power, but do not have the capability of providing electrical power.

In this example, in electrical power distribution system 400, electrical unit 402 includes an electrical sub-unit 438, an electrical sub-unit 440 and an electrical sub-unit 442. Electrical unit 404 includes an electrical sub-unit 444, an electrical sub-unit 446 and an electrical sub-unit 448. Electrical unit 406 includes an electrical sub-unit 450, an electrical sub-unit 452 and an electrical sub-unit 454. Electrical unit 408 includes an electrical sub-unit 456, an electrical sub-unit 458 and an electrical sub-unit 460. Electrical unit 410 includes an electrical sub-unit 462, an electrical sub-unit 464 and an electrical sub-unit 466. Electrical unit 412 includes an electrical sub-unit 468, an electrical sub-unit 470 and an electrical sub-unit 472. Electrical unit 414 includes an electrical sub-unit 474, an electrical sub-unit 476 and an electrical sub-unit 478. Electrical unit 416 includes an electrical sub-unit 480, an electrical sub-unit 482 and an electrical sub-unit 484. Electrical unit 418 includes an electrical sub-unit 486, an electrical sub-unit 488 and an electrical sub-unit 490.

The electrical sub-units in electrical power distribution system 400 are arranged such that the first electrical sub-unit is operable to provide electrical power to the other two sub-units. For example, electrical sub-unit 438, electrical sub-unit 444, electrical sub-unit 450, electrical sub-unit 456, electrical sub-unit 462, electrical sub-unit 468, electrical sub-unit 474, electrical sub-unit 480 and electrical sub-unit 486 of electrical unit 402, electrical unit 404, electrical unit 406, electrical unit 408, electrical unit 410, electrical unit 412, electrical unit 414, electrical unit 416 and electrical unit 418 are arranged to provide electrical power to the other two electrical sub-units within their respective electrical units.

Within electrical unit 402, electrical sub-unit 438 is arranged to receive electrical power from power line 420, perform some function as needed, consume electrical power based on performance of function performed, provide electrical power to electrical sub-unit 440 by way of a power line 401 and provide power as needed to electrical sub-unit 442 by way of a power line 403.

Within electrical unit 404, electrical sub-unit 444 is arranged to receive electrical power from power line 422, perform some function as needed, consume electrical power based on performance of function performed, provide electrical power to electrical sub-unit 446 by way of a power line 405 and provide power as needed to electrical sub-unit 448 by way of a power line 407.

Within electrical unit 406, electrical sub-unit 450 is arranged to receive electrical power from a power line 424, perform some function as needed, consume electrical power based on performance of function performed, provide electrical power to electrical sub-unit 452 by way of power line 409 and provide power as needed to electrical sub-unit 454 by way of a power line 411.

Within electrical unit 408, electrical sub-unit 456 is arranged to receive electrical power from a power line 426, perform some function as needed, consume electrical power based on performance of function performed, provide electrical power to electrical sub-unit 458 by way of power line 413 and provide power as needed to electrical sub-unit 460 by way of a power line 415.

Within electrical unit 410, electrical sub-unit 462 is arranged to receive electrical power from power line 428, perform some function as needed, consume electrical power based on performance of function performed, provide electrical power to electrical sub-unit 464 by way of a power line 417 and provide power as needed to electrical sub-unit 466 by way of a power line 419.

Within electrical unit 412, electrical sub-unit 468 is arranged to receive electrical power from power line 430, perform some function as needed, consume electrical power based on performance of function performed, provide electrical power to electrical sub-unit 470 by way of a power line 421 and provide power as needed to electrical sub-unit 472 by way of a power line 423.

Within electrical unit 414, electrical sub-unit 474 is arranged to receive electrical power from power line 432, perform some function as needed, consume electrical power based on performance of function performed, provide electrical power to electrical sub-unit 476 by way of a power line 425 and provide power as needed to electrical sub-unit 478 by way of a power line 427.

Within electrical unit 416, electrical sub-unit 480 is arranged to receive electrical power from power line 434, perform some function as needed, consume electrical power based on performance of function performed, provide electrical power to electrical sub-unit 482 by way of a power line 429 and provide power as needed to electrical sub-unit 484 by way of a power line 431.

Within electrical unit 418, electrical sub-unit 486 is arranged to receive electrical power from power line 436, perform some function as needed, consume electrical power based on performance of function performed, provide electrical power to electrical sub-unit 488 by way of a power line 433 and provide power as needed to electrical sub-unit 490 by way of a power line 435.

For purposes of discussion, in this example, presume that an amount of power consumption of each electrical unit is based on the total sum of the power consumption of the internal distributed electrical system, therein. For example, presume that an electrical sub-unit will consume three units of power per hour (uph) when performing its designated function. Further, presume that each electrical sub-unit consumes one uph when it is not performing its designated function, for example when in a sleep mode.

To aid in the discussion, electrical sub-units that are operational are illustrated with a dot and electrical sub-units that are non-operational are illustrated without a dot.

Presume for purposes of discussion that in this example, electrical unit 402, electrical unit 404 and electrical unit 410 each have three electrical sub-units in operation and therefore each of these electrical units is consuming nine uph. Electrical unit 406 has two electrical sub-units in operation and therefore is consuming seven uph. Electrical unit 412 and electrical unit 414 each have a single electrical sub-unit in operation and therefore are each consuming five uph. Additionally, electrical unit 408, electrical unit 416 and electrical unit 418 have no electrical sub-units that are operational and therefore are each consuming 3 uph.

As illustrated by electrical unit 408, electrical unit 416 and electrical unit 418, even though all of the electrical sub-units are nonoperational, each electrical unit continues to consume 3 uph.

In the figure, electrical power distribution system 400 is consuming a total of 53 uph, with three out of the nine electrical units not operating at all, and three other electrical units not fully operational (some electrical sub-units not operating).

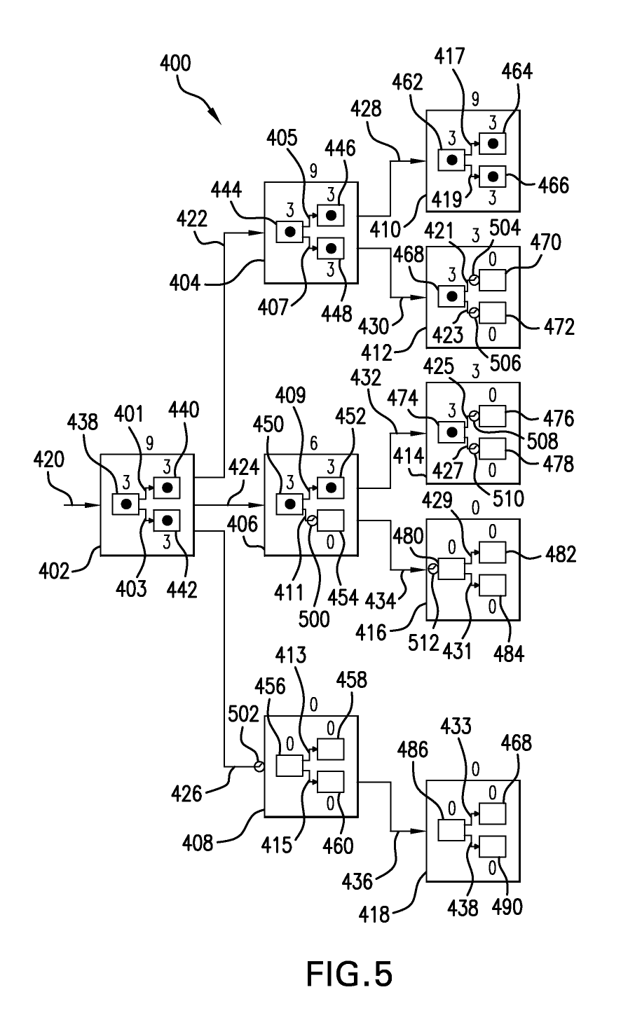

Aspects in accordance with the present invention may be implemented in electrical power distribution system 400 to reduce electrical power consumption by removing electrical power to electrical units and electrical sub-units that are not in use. This will be described with reference to FIG. 5.

FIG. 5 illustrates electrical power distribution system 400, which has been incorporated with CSAs, in accordance with aspects of the present invention.

Presume that electrical units and the power lines providing electrical power to the electrical units are configured with a conventional electrical connector assembly in a manner similar as illustrated above in FIG. 2A. Further, presume that electrical sub-units and the power lines providing electrical power to the electrical sub-units are configured with a conventional fuse and fuse hold assembly in a manner similar as illustrated above in FIG. 3A. Any conventional connector assembly or fuse assembly may be used in FIG. 5, but for the purposes of discussion the connector assembly of FIG. 2A and the fuse assembly of FIG. 3A are used for purposes of illustration.

A control switch in accordance with an aspect of the present invention may be placed on any or all of the electrical power inputs of the electrical units and/or electrical sub-units. Configuring the electrical system with control switches on the input power of all electrical units and electrical sub-units enables complete control of electrical power consumption. Configuring the electrical system with control switches on a portion of the input power for the electrical units and sub-units enables partial control of electrical power consumption.

For purposes of discussion, a control switch is provided on the input power to every electrical unit and sub-unit in the figure. To expedite discussion, only the switches that are configured as open will be illustrated and discussed.

As illustrated in FIG. 5, electrical power distribution system 400 has been modified to include a plurality of CSA's, which include CSA 500, a CSA 502, a CSA 504, a CSA 506, a CSA 508 a CSA 510 and CSA 512.

CSA 500 is located between power line 411 and electrical sub-unit 454. CSA 502 is connected between power line 426 and electrical unit 408. CSA 504 is located between power line 421 and electrical sub-unit 470. CSA 506 is located between power line 423 and electrical sub-unit 472. CSA 508 is located between power line 425 and electrical sub-unit 476. CSA 510 is located between power line 427 and electrical sub-unit 478. CSA 512 is located between power line 434 and electrical unit 416.

In this figure, each CSA is in the open state, which cuts off power to a respective electrical unit or electrical sub unit. Accordingly, electrical power distribution system 400 as modified in accordance with aspects of the present invention is consuming a total of 39 uph. This is a 26% reduction in power consumption over electrical power distribution system 400 as illustrated in FIG. 4.

The example aspect of the present invention illustrated in FIG. 5 provides the capability to turn off specific units and/or their respective sub-units via CSAs connected between the equipment and sources of power. Electronic sub-units that would conventionally consume 1 uph when in a non-operational mode will therefore not consume any power as a result of the example aspect of the present invention.

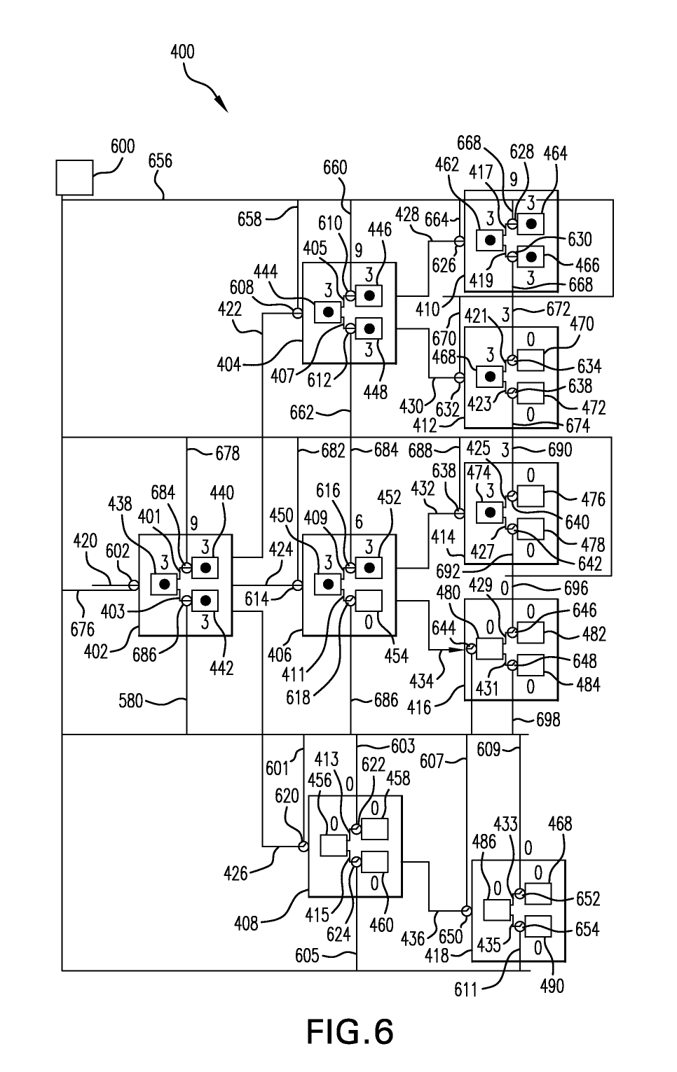

FIG. 5 illustrates how an example aspect of the present invention can be used to turn off non-operational portions of a distributed electrical power distribution system such that the non-operational portions do not consume power. FIG. 6 illustrates how an example aspect of the present invention can be used to turn on or turn off portions of a distributed electrical power system from an external control unit.

FIG. 6 is the distributed electrical power distribution system illustrated in FIG. 4 and FIG. 5 with the addition of an example aspect of the present invention provided for externally controlling the on/off state of the system.

The figure includes a control unit 600, a CSA 602, a CSA 604, a CSA 606, a CSA 608, a CSA 610, a CSA 612, a CSA 614, a CSA 616, a CSA 618, a CSA 620, a CSA 622, a CSA 624, a CSA 626, a CSA 628, a CSA 630, a CSA 632, a CSA 634, a CSA 636, a CSA 638, a CSA 640, a CSA 642, a CSA 644, a CSA 646, a CSA 648, a CSA 650, a CSA 652, a CSA 654, a control bus 656, a control signal 658, a control signal 660, a control signal 662, a control signal 664, a control signal 666, a control signal 668, a control signal 670, a control signal 672, a control signal 674, a control signal 676, a control signal 678, a control signal 680, a control signal 682, a control signal 684, a control signal 686, a control signal 688, a control signal 690, a control signal 692, a control signal 694, a control signal 696, a control signal 698, a control signal 601, a control signal 603, a control signal 605 a control signal 607, a control signal 609 and a control signal 611.

CSA 602 is located between power line 420 and electrical unit 402. CSA 606 is located between power line 403 and electrical sub-unit 442. CSA 604 is located between power line 401 and electrical sub-unit 440. CSA 608 is located between power line 422 and electrical unit 404. CSA 610 is located between power line 405 and electrical sub-unit 446. CSA 612 is located between power line 407 and electrical sub-unit 448. CSA 626 is located between power line 428 and electrical unit 410. CSA 628 is located between power line 417 and electrical sub-unit 464. CSA 630 is located between power line 419 and electrical sub-unit 466. CSA 632 is located between power line 430 and electrical unit 412. CSA 634 is located between power line 421 and electrical sub-unit 470. CSA 636 is located between power line 423 and electrical sub-unit 472. CSA 638 is located between power line 432 and electrical unit 414. CSA 640 is located between power line 425 and electrical sub-unit 476. CSA 642 is located between power line 427 and electrical sub-unit 478. CSA 614 is located between power line 424 and electrical unit 406. CSA 616 is located between power line 409 and electrical sub-unit 452. CSA 618 is located between power line 411 and electrical sub-unit 454. CSA 644 is located between power line 434 and electrical unit 416. CSA 646 is located between power line 429 and electrical sub-unit 482. CSA 648 is located between power line 431 and electrical sub-unit 484. CSA 620 is located between power line 426 and electrical unit 408. CSA 622 is located between power line 413 and electrical sub-unit 458. CSA 624 is located between power line 415 and electrical sub-unit 460. CSA 650 is located between power line 436 and electrical unit 418. CSA 652 is located between power line 433 and electrical sub-unit 488. CSA 654 is located between power line 435 and electrical sub-unit 490.

Control unit 600 is connected to control bus 656. Each control signal is connected to control bus 656, which enables control unit 600 to control the on/off state of each CSA.

Control signal 658 is located between control bus 656 and CSA 608. Control signal 660 is located between control bus 656 and CSA 610. Control signal 662 is located between control bus 656 and CSA 612. Control signal 664 is located between control bus 656 and CSA 626. Control signal 666 is located between control bus 656 and CSA 628. Control signal 668 is located between control bus 656 and CSA 630. Control signal 670 is located between control bus 656 and CSA 632. Control signal 672 is located between control bus 656 and CSA 634. Control signal 674 is located between control bus 656 and CSA 636. Control signal 676 is located between control bus 656 and CSA 602. Control signal 678 is located between control bus 656 and CSA 604. Control signal 680 is located between control bus 656 and CSA 606. Control signal 682 is located between control bus 656 and CSA 614. Control signal 684 is located between control bus 656 and CSA 616. Control signal 686 is located between control bus 656 and CSA 618. Control signal 688 is located between control bus 656 and CSA 638. Control signal 690 is located between control bus 656 and CSA 640. Control signal 692 is located between control bus 656 and CSA 642. Control signal 694 is located between control bus 656 and CSA 644. Control signal 696 is located between control bus 656 and CSA 646. Control signal 698 is located between control bus 656 and CSA 648. Control signal 601 is located between control bus 656 and CSA 620. Control signal 603 is located between control bus 656 and CSA 622. Control signal 605 is located between control bus 656 and CSA 624. Control signal 607 is located between control bus 656 and CSA 650. Control signal 609 is located between control bus 656 and CSA 652. Control signal 611 is located between control bus 656 and CSA 654.

Control unit 600 controls the on/off state of each electrical unit and each electrical sub-unit, as well as each downstream electrical unit and electrical sub-unit via control signals transmitted to each CSA.

For example, if control unit 600 were to configure CSA 602 to the off state via control bus 656 and control signal 676, electrical unit 402 would transition to the off state. Additionally every other electrical unit and electrical sub-unit would also transition to the off state, as all of the electrical units and electrical sub-units are downstream of electrical unit 402.

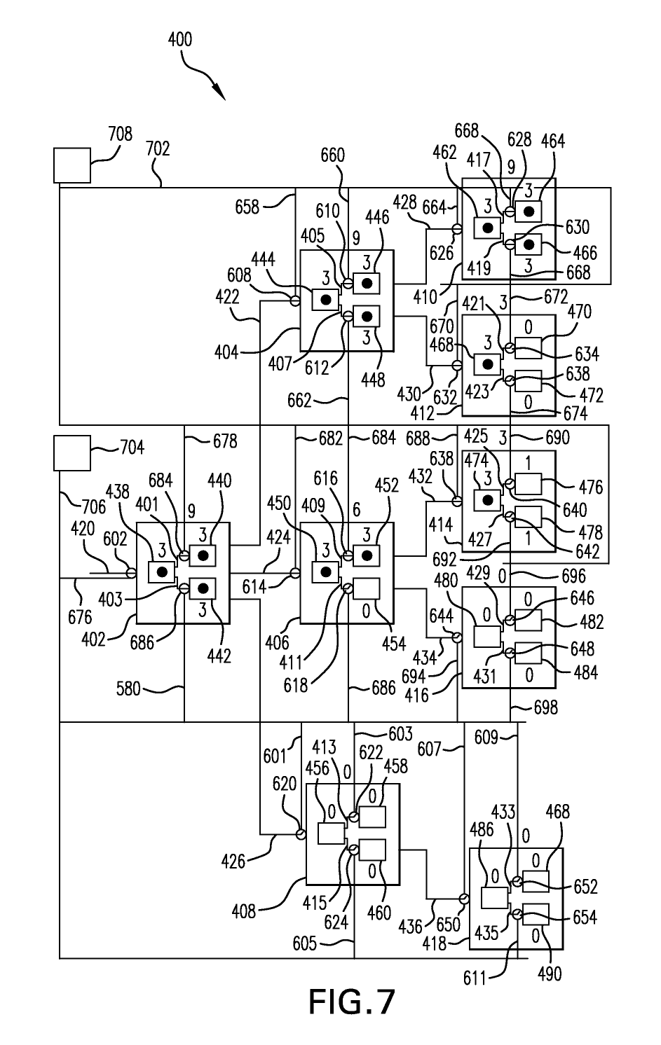

FIG. 6 illustrates how an example aspect of the present invention can be used to turn on or off portions of a distributed electrical power system from an external control unit. FIG. 7 will illustrate how an example aspect of the present invention can be used to turn on or off portions of a distributed electrical power distribution from multiple external control units.

FIG. 7 is the distributed electrical power distribution system illustrated in FIG. 4 through FIG. 6 with the addition of an example aspect of the present invention provided for externally controlling the on/off state of the system via multiple control units.

FIG. 7 includes a control unit 700, a control bus 702, a control unit 704 and a control bus 706.

Control unit 700 is connected to control bus 702. Each control signal connected to control bus 702 provides a way for control unit 700 to control the on/off state of each CSA which is connected to a control signal which is also connected to control bus 702.

Control unit 704 is connected to control bus 706. Each control signal connected to control bus 706 provides a way for control unit 704 to control the on/off state of each CSA which is connected to a control signal which is also connected to control bus 706.

Control signal 658 is located between control bus 702 and CSA 608. Control signal 660 is located between control bus 702 and CSA 610. Control signal 662 is located between control bus 702 and CSA 612. Control signal 664 is located between control bus 702 and CSA 626. Control signal 666 is located between control bus 702 and CSA 628. Control signal 668 is located between control bus 702 and CSA 630. Control signal 670 is located between control bus 702 and CSA 632. Control signal 672 is located between control bus 702 and CSA 634. Control signal 674 is located between control bus 702 and CSA 636. Control signal 678 is located between control bus 702 and CSA 604. Control signal 682 is located between control bus 702 and CSA 614. Control signal 684 is located between control bus 702 and CSA 616. Control signal 688 is located between control bus 702 and CSA 638. Control signal 690 is located between control bus 702 and CSA 640. Control signal 692 is located between control bus 702 and CSA 642. Control signal 696 is located between control bus 702 and CSA 646.

Control signal 676 is located between control bus 706 and CSA 602. Control signal 680 is located between control bus 706 and CSA 606. Control signal 686 is located between control bus 706 and CSA 618. Control signal 694 is located between control bus 706 and CSA 644. Control signal 698 is located between control bus 706 and CSA 648. Control signal 601 is located between control bus 706 and CSA 620. Control signal 603 is located between control bus 706 and CSA 622. Control signal 605 is located between control bus 706 and CSA 624. Control signal 607 is located between control bus 706 and CSA 650. Control signal 609 is located between control bus 706 and CSA 652. Control signal 611 is located between control bus 706 and CSA 654.

As shown in FIG. 7, control unit 700 controls a portion of the CSAs and control unit 704 controls the remaining portion of the CSAs.

Control unit 700 has on/off control of CSA 604, CSA 608, CSA 610, CSA 612, CSA 626, CSA 628, CSA 630, CSA 632, CSA 634, CSA 636, CSA 638, CSA 640, CSA 642, CSA 614, CSA 616 and CSA 646.

Control unit 704 has on/off control of CSA 602, CSA 606, CSA 618, CSA 644, CSA 648, CSA 620, CSA 622, CSA 624, CSA 650, CSA 652 and CSA 654.

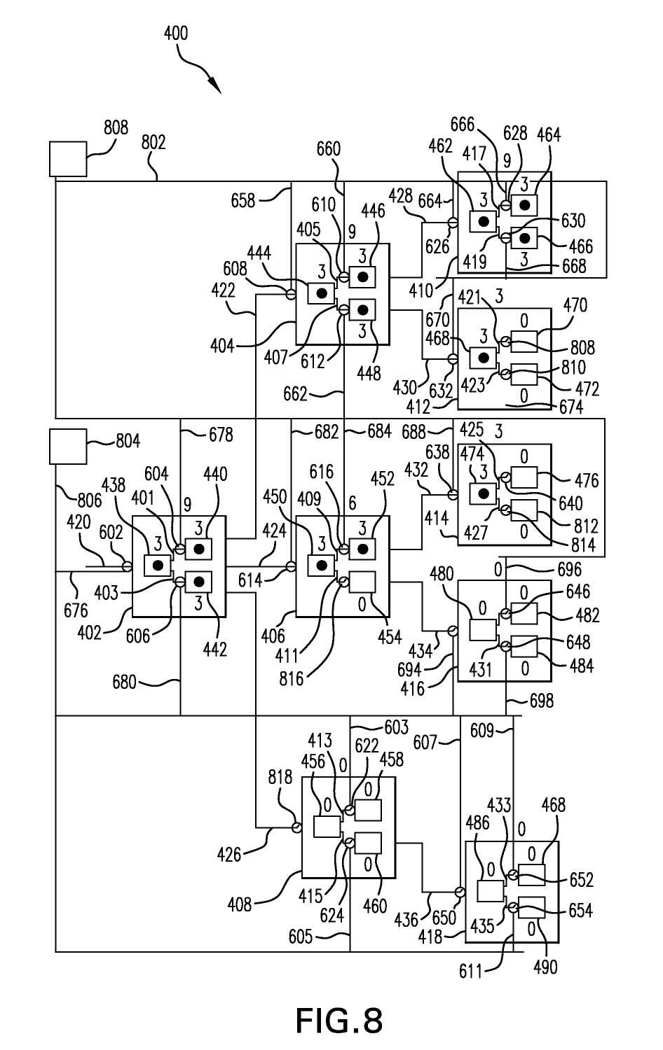

FIG. 7 illustrates how an example aspect of the present invention can be used to turn on or off portions of a distributed electrical power system from multiple external control units. FIG. 8 will illustrate how an example aspect of the present invention can be used to turn on or off portions of a distributed electrical power distribution from multiple external control units and also via internal control.

FIG. 8 is the distributed electrical power distribution system illustrated in FIG. 4 through FIG. 7 with the addition of an example aspect of the present invention provided for externally controlling the on/off state of a portion of the system via multiple control units and also controlling the on/off state of a portion of the system via internal control.

The figure includes a control unit 800, a control bus 802, a control unit 804, a control bus 806, a CSA 808, a CSA 810, a CSA 812, a CSA 814, a a CSA 816 and a CSA 818.

Control unit 800 is connected to control bus 802. Each control signal connected to control bus 802 provides a way for control unit 800 to control the on/off state of each CSA which is connected to a control signal which is also connected to control bus 802.

Control unit 804 is connected to control bus 806. Each control signal connected to control bus 806 provides a way for control unit 804 to control the on/off state of each CSA which is connected to a control signal which is also connected to control bus 806.

Control signal 658 is located between control bus 802 and CSA 608. Control signal 660 is located between control bus 802 and CSA 610. Control signal 662 is located between control bus 802 and CSA 612. Control signal 664 is located between control bus 802 and CSA 626. Control signal 666 is located between control bus 802 and CSA 628. Control signal 668 is located between control bus 802 and CSA 630. Control signal 670 is located between control bus 802 and CSA 632. Control signal 678 is located between control bus 802 and CSA 604. Control signal 682 is located between control bus 802 and CSA 614. Control signal 684 is located between control bus 802 and CSA 616. Control signal 688 is located between control bus 802 and CSA 638. Control signal 696 is located between control bus 802 and CSA 646.

Control signal 676 is located between control bus 806 and CSA 602. Control signal 680 is located between control bus 806 and CSA 606. Control signal 694 is located between control bus 806 and CSA 644. Control signal 698 is located between control bus 806 and CSA 648. Control signal 603 is located between control bus 806 and CSA 622. Control signal 605 is located between control bus 806 and CSA 624. Control signal 607 is located between control bus 806 and CSA 650. Control signal 609 is located between control bus 806 and CSA 652. Control signal 611 is located between control bus 806 and CSA 654.

As shown in FIG. 8, control unit 800 controls a portion of the CSAs, control unit 804 controls another portion of the CSAs and the remaining CSAs are internally controlled.

Control unit 800 has on/off control of CSA 604, CSA 608, CSA 610, CSA 612, CSA 626, CSA 628, CSA 630, CSA 632, CSA 638, CSA 614, CSA 616 and CSA 646.

Control unit 804 has on/off control of CSA 602, CSA 606, CSA 644, CSA 648, CSA 622, CSA 624, CSA 650, CSA 652 and CSA 654.

CSA 808, CSA 810, CSA 814, CSA 812, CSA 816 and CSA 818 are internally control led.

FIG. 8 illustrates how an example aspect of the present invention can be used to turn on or off portions of a distributed electrical power distribution from multiple external control units and also via internal control.

The example embodiments of CSA illustrated above with reference to FIGS. 2A-3B are non-limiting examples. A CSA in accordance with aspects of the present invention may take any form that is operable to controllably connect/disconnect an electrical device from a power source.

Aspects of the present invention provide a way for legacy electronic equipment as well as current and future generations of equipment to be economically controlled with respect to power consumption. Devices in accordance with aspects of the present invention can be retroactively inserted between existing equipment and its power sources in order to turn off the equipment when it is in a non-operational mode and to turn the equipment on when it is to be in an operational mode. The capability of turning on and off electronic equipment enables a reduction in power consumption over a legacy system which does not implement any control over power consumption.

What is claimed as new and desired to be protected by Letters Patent of the United States is:

1. A device for use with a power supply line and an electrical unit, the power supply line having a first connecting portion, the electrical unit having a second connecting portion, the first connecting portion being operable to detachably connect with the second connecting portion, the electrical unit being operable to perform a function when the first connecting portion is electrically connected to the second connecting portion, the electrical unit being further operable to consume power provided from the power supply line when not perfoming the function, said device comprising:
a third connecting portion operable to detachably connect to the first connecting portion;
a fourth connecting portion operable to detachably connect to the second connecting portion;
a switching device operable to electrically connect said third connecting portion to said fourth connecting portion when in a first state and to electrically disconnect said third connecting portion from said fourth connecting portion when in a fourth state; and
a control line operable to switch said switching device from the first state to the second state.

2. The device of claim 1, wherein said switching device comprises a transistor.

3. The device of claim 1, wherein said switching device comprises a plurality of transistors.

4. The device of claim 3, wherein said plurality of transistors comprises an array of transistors.

5. The device of claim 1, wherein said switching device comprises a relay.

6. The device of claim 1, wherein said switching device comprises a plurality of relays.

7. The device of claim 6, wherein said plurality of transistors comprises an array of relays.

8. A method of controllably providing electrical power from a power supply line to an electrical unit, the power supply line having a first connecting portion, the electrical unit having a second connecting portion, the first connecting portion being operable to detachably connect with the second connecting portion, the electrical unit being operable to perform a function when the first connecting portion is electrically connected to the second connecting portion, the electrical unit being further operable to consume power provided from the power supply line when not performing the function, said method comprising:
connecting a third connecting portion of a device having a switching portion to the first connecting portion;
connecting a fourth connecting portion of the device to the second connecting portion;
controlling, by way of a control line, the switching device to electrically connect the third connecting portion to the fourth connecting portion.

9. The method of claim 8, further comprising controlling, by way of the control line, the switching device to electrically disconnect the third connecting portion from the fourth connecting portion.

10. The method of claim 9, wherein said connecting a third connecting portion of a device having a switching portion to the first connecting portion comprises connecting a third connecting portion of a device having a transistor to the first connecting portion.

11. The method of claim 9, wherein said connecting a third connecting portion of a device having a switching portion to the first connecting portion comprises connecting a third connecting portion of a device having a plurality of transistors to the first connecting portion.

12. The method of claim 11, wherein connecting a third connecting portion of a device having a plurality of transistors to the first connecting portion comprises connecting the third connecting portion of a device having an array of transistors to the first connecting portion.

13. The method of claim 9, wherein said connecting a third connecting portion of a device having a switching portion to the first connecting portion comprises connecting the third connecting portion of a device having a relay to the first connecting portion.

14. The method of claim 9, wherein said connecting a third connecting portion of a device having a switching portion to the first connecting portion comprises connecting a third connecting portion of a device having a plurality of relays to the first connecting portion.

15. The device of claim 14, wherein connecting a third connecting portion of a device having a plurality of relays to the first connecting portion comprises connecting a third connecting portion of a device having an array of relays to the first connecting portion.

16. The method of claim 8, wherein said connecting a third connecting portion of a device having a switching portion to the first connecting portion comprises connecting a third connecting portion of a device having a transistor to the first connecting portion.

17. The method of claim 8, wherein said connecting a third connecting portion of a device having a switching portion to the first connecting portion comprises connecting a third connecting portion of a device having a plurality of transistors to the first connecting portion.

18. The method of claim 17, wherein connecting a third connecting portion of a device having a plurality of transistors to the first connecting portion comprises connecting a third connecting portion of a device having an array of transistors to the first connecting portion.

19. The method of claim 8, wherein said connecting a third connecting portion of a device having a switching portion to the first connecting portion comprises connecting a third connecting portion of a device having a relay to the first connecting portion.

20. The method of claim 8, wherein said connecting a third connecting portion of a device having a switching portion to the first connecting portion comprises connecting a third connecting portion of a device having a plurality of relays to the first connecting portion.
